(19) United States
(12) Patent Application Publication
(10) Pub. No.: US 2008/0308933 A1
(43) Pub. Date: Dec. 18, 2008

(54) INTEGRATED CIRCUIT PACKAGE SYSTEM WITH DIFFERENT CONNECTION STRUCTURES

(76) Inventors: Lionel Chien Hui Tay, Singapore (SG); Zigmund Ramirez Camacho, Singapore (SG); Abelardo Hadap Advincula, Singapore (SG)

Correspondence Address: LAW OFFICES OF MIKIO ISHIMARU, 333 W. EL CAMINO REAL, SUITE 330, SUNNYVALE, CA, 94087, US

(21) Appl. No.: 11/763,154

(22) Filed: Jun. 14, 2007

(51) Int. Cl. H01L 23/48; H01L 21/60

(52) U.S. Cl. 257/738; 438/108; 438/127; 257/E21.506; 257/E23.01

(57) ABSTRACT

An integrated circuit package system is provided including forming an external interconnect having a tip without a die-attach paddle; mounting a first integrated circuit device structure having a conductive ball over the tip; connecting a first wire between the first integrated circuit device structure and under the tip; and encapsulating the first integrated circuit device structure, the first wire, and the external interconnect with the external interconnect partially exposed.

### TECHNICAL FIELD

The present invention relates generally to an integrated circuit package system, and more particularly to an integrated circuit package system with an encapsulation.

### BACKGROUND ART

Modern consumer electronics, such as cellular phones, digital cameras, and music players, are packing more integrated circuits into an ever-shrinking physical space with expectations for decreasing cost. Numerous technologies have been developed to meet these requirements. Some of the research and development strategies focus on new technologies while others focus on improving the existing and mature technologies. Research and development in the existing technologies may take a myriad of different directions.

Consumer electronics requirements demand more integrated circuits in an integrated circuit package while paradoxically providing less physical space in the system for the increased integrated circuits content. Continuous cost reduction is another requirement. Some technologies primarily focus on integrating more functions into each integrated circuit. Other technologies focus on stacking these integrated circuits into a single package. While these approaches provide more functions within an integrated circuit, they do not fully address the requirements for lower height, smaller space, and cost reduction.

One proven way to reduce cost is to use mature package technologies with existing manufacturing methods and equipments. Paradoxically, the reuse of existing manufacturing processes does not typically result in the reduction of package dimensions. Still the demand continues for lower cost, smaller size, and more functionality. Continued integration of functions into a single integrated circuit increases the integrated circuit size necessitating a more expensive package or a higher profile package.

To further condense the packaging of individual devices, packages have been developed in which more than one device can be packaged on a package site of a lead frame strip. Each package site on a lead frame strip is a structure that provides mechanical support for the individual IC dice. It also provides one or more layers of interconnect lines that enable the devices to be connected electrically to surrounding circuitry. Various chip-on-board (“COB”) techniques are used to attach different semiconductor die to a printed circuit board (“PCB”). COB techniques include flip chip attachment, wire bonding, and tape automated bonding (“TAB”).

In some cases, multi-chip devices can be fabricated faster and more cheaply than a corresponding single IC chip that incorporates all the same functions. Current multi-chip modules typically consist of a PCB substrate onto which a set of separate IC chip components is directly attached. Such multi-chip modules have been found to increase circuit density and miniaturization, improve signal propagation speed, reduce overall device size and weight, improve performance, and lower costs, all of which are primary goals of the computer industry.

However, such multi-chip modules can be bulky. The area required to mount a die or module on a circuit board determines the IC package density. One method for reducing the board size of multi-chip modules and thereby increase their effective density is to stack the die or chips vertically within the module or package. In one design, a pair of IC die is mounted on opposite sides of a lead frame paddle. Gold or aluminum wires then connect the wire bonding pads on both the upper die and the lower die with the ends of their associated lead frame lead extensions.

Higher integration can be achieved through chip scale package (CSP) applications such as flip chip technology. Flip chip technology can employ area arrays for bump pads including connections to a carrier, thereby reducing package area and shortening transmission paths. A flip chip is generally a semiconductor device, such as an integrated circuit, having bead-like terminals formed on one surface of the chip. The terminals serve to both secure the chip to a circuit board and electrically connect the flip chip's circuitry to a conductor pattern formed on the circuit board, which may be a ceramic substrate, printed wiring board, flexible circuit, a substrate, or a lead frame. The typical flip chip is generally quite small, resulting in the terminals being crowded along the perimeter. As a result, conductor patterns are typically composed of numerous conductors often spaced closely.

Flip chip offers increased I/O density but not be the best interconnect option for other integrated circuit devices. For example, integrated circuits providing a large number of functions may benefit from the flip chip interface. Other devices may have dense and repetitive functions, such as memory devices, that do not require a flip chip interface and may be more cost effective to use wire bonding.

To meet this demand, the integrated circuit packages, such as quad flat nonleaded (QFN) package, are becoming popular owing to its small form factor, good thermal and electrical performance. A combination of the QFN package and flip chip technology would provide an attractive package. However, one problem in conventionally assembly of a flip chip on QFN lead frame is the challenge of integrating various other types of integrated circuits with different interfaces into a single package.

Thus, a need still remains for an integrated circuit package system providing low cost manufacturing, improved yield, improved reliability, multiple integrated circuit integration with a flip chip in a package, and low profile. In view of the ever-increasing need to save costs and improve efficiencies, it is more and more critical that answers be found to these problems.

Solutions to these problems have been long sought but prior developments have not taught or suggested any solutions and, thus, solutions to these problems have long eluded those skilled in the art.

### DISCLOSURE OF THE INVENTION

The present invention provides an integrated circuit package system including forming an external interconnect having a tip without a die-attach paddle; mounting a first integrated circuit device structure having a conductive ball over the tip; connecting a first wire between the first integrated circuit device structure and under the tip; and encapsulating the first integrated circuit device structure, the first wire, and the external interconnect with the external interconnect partially exposed.

Certain embodiments of the invention have other aspects in addition to or in place of those mentioned above. The aspects will become apparent to those skilled in the art from a reading of the following detailed description when taken with reference to the accompanying drawings.

### BRIEF DESCRIPTION OF THE DRAWINGS

FIG. 1 is a bottom view of an integrated circuit package system in a first embodiment of the present invention;

FIG. 2 is a cross-sectional view of the integrated circuit package system along line 2-2 of FIG. 1;

FIG. 3 is a cross-sectional view of an integrated circuit package system as exemplified by the bottom view of FIG. 1 along line 2-2 of FIG. 1 in a second embodiment of the present invention;

FIG. 4 is a cross-sectional view of an integrated circuit package system as exemplified by the bottom view of FIG. 1 along line 2-2 of FIG. 1 in a third embodiment of the present invention;

FIG. 5 is a cross-sectional view of an integrated circuit package system as exemplified by the bottom view of FIG. 1 along line 2-2 of FIG. 1 in a fourth embodiment of the present invention;

FIG. 6 is a cross-sectional view of an integrated circuit package system as exemplified by the bottom view of FIG. 1 along line 2-2 of FIG. 1 in a fifth embodiment of the present invention;

FIG. 7 is a cross-sectional view of an integrated circuit package system as exemplified by the bottom view of FIG. 1 along line 2-2 of FIG. 1 in a sixth embodiment of the present invention;

FIG. 8 is a cross-sectional view of an integrated circuit package system as exemplified by the bottom view of FIG. 1 along line 2-2 of FIG. 1 in a seventh embodiment of the present invention

FIG. 9 is a cross-sectional view of an integrated circuit package system as exemplified by the bottom view of FIG. 1 along line 2-2 of FIG. 1 in a eighth embodiment of the present invention;

FIG. 10 is a cross-sectional view of a lead frame in a mounting phase of the first integrated circuit device structure;

FIG. 11 is the structure of FIG. 10 in a vertically flipped orientation in a mounting phase of the second integrated circuit device structure;

FIG. 12 is the structure of FIG. 11 in a connecting phase of the first wires;

FIG. 13 is the structure of FIG. 12 in a non-vertically flipped orientation in a forming phase of the package encapsulation; and

FIG. 14 is a flow chart of an integrated package system for manufacturing the integrated circuit package system in an embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail. Likewise, the drawings showing embodiments of the system are semi-diagrammatic and not to scale and, particularly, some of the dimensions are for the clarity of presentation and are shown greatly exaggerated in the drawing FIGS.

In addition, where multiple embodiments are disclosed and described having some features in common, for clarity and ease of illustration, description, and comprehension thereof, similar and like features one to another will ordinarily be described with like reference numerals. The embodiments have been numbered first embodiment, second embodiment, etc. as a matter of descriptive convenience and are not intended to have any other significance or provide limitations for the present invention.

For expository purposes, the term “horizontal” as used herein is defined as a plane parallel to the plane or surface of the integrated circuit, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane. The term “on” means there is direct contact among elements. The term “processing” as used herein includes deposition of material, patterning, exposure, development, etching, cleaning, molding, and/or removal of the material or as required in forming a described structure. The term “system” as used herein means and refers to the method and to the apparatus of the present invention in accordance with the context in which the term is used. The term “integrated circuit device structure” as used herein means and refers to embedded structures of the present invention including embedded structures having integrated circuits or embedded structures for providing redistribution of electrical connections with integrated circuits.

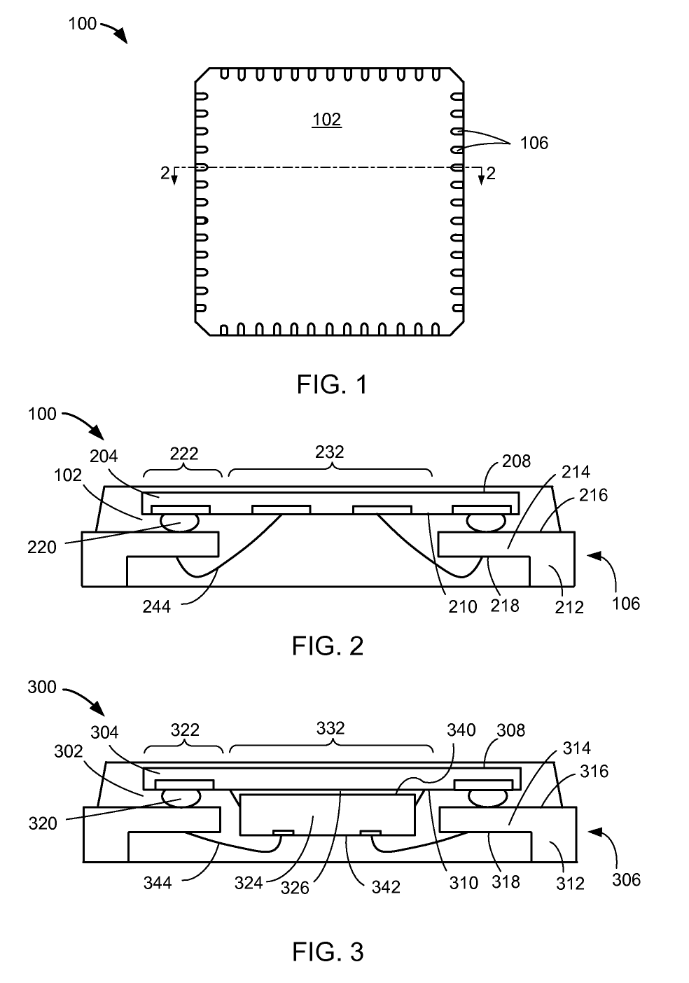

Referring now to FIG. 1, therein is shown a bottom view of an integrated circuit package system 100 in a first embodiment of the present invention. The bottom view shows a package encapsulation 102, such as an epoxy molding compound, preferably surrounding and exposing a row of external interconnects 106, such as leads.

For illustrative purposes, the external interconnects 106 are shown in a single row configuration, although it is understood that the external interconnects 106 may be in a different configuration, such as multiple rows. Also for illustrative purposes, a package side of the integrated circuit package system 100 has the external interconnects 106 equally spaced, although it is understood that the integrated circuit package system 100 may have some sites depopulated such that the package side might not have the external interconnects 106 equally spaced.

Referring now to FIG. 2, therein is shown a cross-sectional view of the integrated circuit package system 100 along a line 2-2 of FIG. 1. The cross-sectional view depicts a first integrated circuit device structure 204 preferably mounted over the external interconnects 106. The first integrated circuit device structure 204, such as a flip chip or an integrated circuit die, has a first non-electrical contact side 208, such as a non-active side, and a first electrical contact side 210, such as an active side, wherein the first electrical contact side 210 includes active circuitry fabricated thereon. The first electrical contact side 210 is facing the external interconnects 106.

Each of the external interconnects 106 includes a body 212 and a tip 214, wherein the tip 214 has a first connect side 216 and a second connect side 218 on an opposing side to the first connect side 216. The first integrated circuit device structure 204 is preferably mounted over the first connect side 216 with conductive balls 220, such as conductive balls or conductive bumps comprised of solder or gold, preferably electrically connecting a peripheral portion 222 of the first electrical contact side 210 of the first integrated circuit device structure 204 to the first connect side 216.

The first integrated circuit device structure 204 is further electrically connected to the second connect side 218 of the tip 214 with first wires 244, such as bond wires, ribbon bond wires, or reverse stand-off stitch bonds (RSSB). The first wires 244 preferably connect to an interior portion 232 of the first electrical contact side 210.

The package encapsulation 102, such as an epoxy molding compound, covers the first integrated circuit device structure 204, the conductive balls 220, and the first wires 244. The package encapsulation 102 partially covers the external interconnects 106 exposing the body 212 of the external interconnects 106 and covering a portion of the tip 214 connected to the conductive balls 220 and the first wires 244.

It has been discovered that the present invention provides an integrated circuit package system with reduced profile from flip chip mounting above the tip of the external interconnect as well as using wire connections from the flip chip to the below the tip of the external interconnect. The mix of solder bumps and wires also reduces the risk of inadvertent shorts of the wires from wire loop sweep during the molding process resulting in improved yield and lower cost.

It has also been discovered that the present invention has electrical bonding to central portions of the mounted integrated circuit device structure is preferably maximized or increased by the elimination of a die-attach paddle (not shown) found in conventional packages that would have obstructed the routing of the additional wires.

For illustrative purposes, the integrated circuit package system 100 is shown with the first integrated circuit device structure 204, however, it is understood that the first integrated circuit device structure 204 may represent more than one integrated circuit stacked in a variety of configurations to create multiple and stacked integrated circuit device structures. The first integrated circuit device structure 204 may also represent different types of integrated circuit device structures, such as an integrated circuit die, an integrated circuit package system having one or more integrated circuit dice, or a laminate having integrated circuit devices mounted thereon.

Referring now to FIG. 3, therein is shown a cross-sectional view of an integrated circuit package system 300 as exemplified by the bottom view of FIG. 1 along line 2-2 of FIG. 1 in a second embodiment of the present invention. The cross-sectional view depicts a first integrated circuit device structure 304 preferably mounted over external interconnects 306, such as leads. The first integrated circuit device structure 304, such as a flip chip or an integrated circuit die, has a first non-electrical contact side 308, such as a non-active side, and a first electrical contact side 310, such as an active side, wherein the first electrical contact side 310 includes active circuitry fabricated thereon. The first electrical contact side 310 faces the external interconnects 306.

Each of the external interconnects 306 includes a body 312 and a tip 314, wherein the tip 314 has a first connect side 316 and a second connect side 318 on an opposing side to the first connect side 316. The first integrated circuit device structure 304 is preferably mounted over the first connect side 316 with conductive balls 320, such as conductive balls or conductive bumps comprised of solder or gold, preferably electrically connecting a peripheral portion 322 of the first electrical contact side 310 of the first integrated circuit device structure 304 to the first connect side 316.

A second integrated circuit device structure 324, such as an integrated circuit die, is preferably mounted under the first integrated circuit device structure 304 with an adhesive 326, such as an epoxy adhesive or a die-attach adhesive. The second integrated circuit device structure 324 is between the external interconnects 306.

The second integrated circuit device structure 324 has a second non-electrical contact side 340, such as a non-active side, and a second electrical contact side 342, such as an active side, wherein the second electrical contact side 342 has active circuitry fabricated thereon. The second non-electrical contact side 340 preferably faces an interior portion 332 of the first electrical contact side 310. The second integrated circuit device structure 324 may be electrically connected to the first integrated circuit device structure 304 by connecting with the same predetermined selection of the external interconnects 306 connected to the conductive balls 320. The second electrical contact side 342 electrically connects to the second connect side 318 of the tip 314 with first wires 344, such as bond wires, ribbon bond wires, or reverse stand-off stitch bonds (RSSB).

A package encapsulation 302, such as an epoxy molding compound, covers the first integrated circuit device structure 304, the conductive balls 320, the second integrated circuit device structure 324, and the first wires 344. The package encapsulation 302 partially covers the external interconnects 306 exposing the body 312 of the external interconnects 306 and covering a portion of the tip 314 connected to the conductive balls 320 and the first wires 344.

For illustrative purposes, the first integrated circuit device structure 304 and the second integrated circuit device structure 324 are shown electrically connected by connecting the same predetermined selection of the external interconnects 306, although it is understood that the first integrated circuit device structure 304 and the second integrated circuit device structure 324 may be otherwise electrically connected. For example, the first wires 344 may connect the second integrated circuit device structure 324 to a predetermined selection of the external interconnects 306 not connected with the conductive balls 320.

Also for illustrative purposes, the integrated circuit package system 300 is shown with the second integrated circuit device structure 324 attached to the first integrated circuit device structure 304, however, it is understood that more than one additional integrated circuit device structures can be stacked and in a variety of possible configurations to create multiple and stacked integrated circuit device structures. For example, the first integrated circuit device structure 304 and the second integrated circuit device structure 324 can each also be of any type of integrated circuit device structures, such as an integrated circuit die, an integrated circuit package system having one or more integrated circuit dice, or a laminate having integrated circuit devices mounted thereon.

It has been discovered that the present invention provides an integrated circuit package system having stacked integrated circuits with reduced profile from mounting the first integrated circuit device structure, such as a flip chip, above the tip of the external interconnect and mounting a second integrated circuit device structure under the first integrated circuit device structure. The wires connecting the second integrated circuit device structure and the second connect side of the tip eliminates inadvertent connections between first integrated circuit device structure and the second integrated circuit device structure.

It has also been discovered that the present invention increases integrated circuit device density in the integrated circuit package system by the elimination of a die-attach paddle (not shown) found in conventional packages that would have obstructed the routing of the additional wire bonds and the stacking of additional integrated circuit device structures.

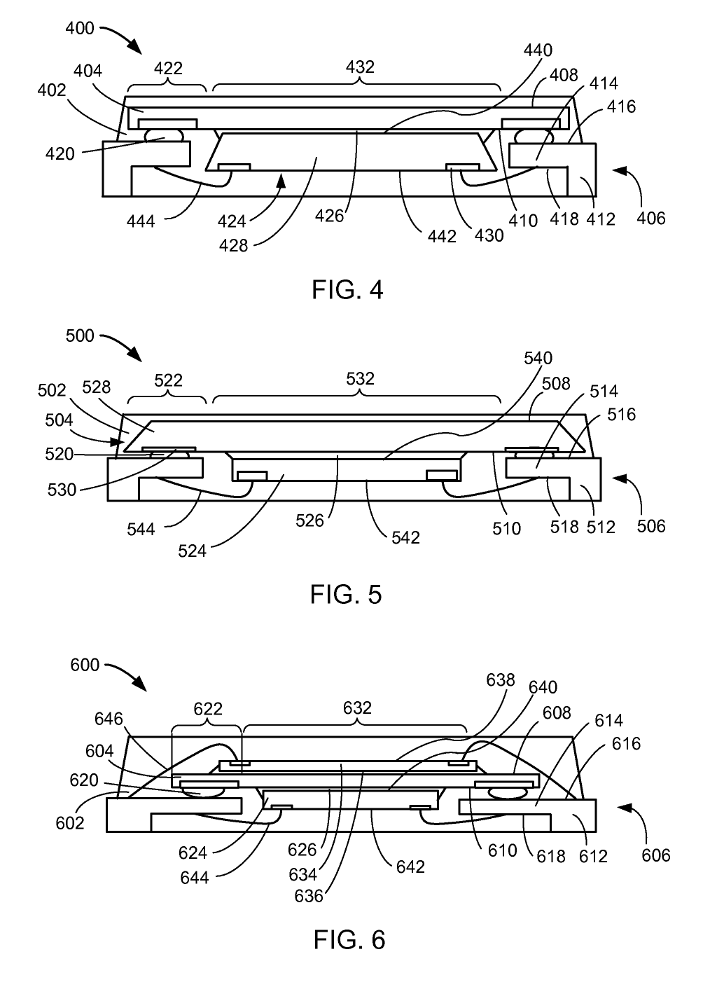

Referring now to FIG. 4, therein is shown a cross-sectional view of an integrated circuit package system 400 as exemplified by the bottom view of FIG. 1 along line 2-2 of FIG. 1 in a third embodiment of the present invention. The integrated circuit package system 400 is an example of an integrated circuit package-in-package system. The cross-sectional view depicts a first integrated circuit device structure 404 preferably mounted over external interconnects 406, such as leads. The first integrated circuit device structure 404, such as a flip chip or an integrated circuit die, has a first non-electrical contact side 408, such as a non-active side, and a first electrical contact side 410, such as an active side, wherein the first electrical contact side 410 includes active circuitry fabricated thereon. The first electrical contact side 410 faces the external interconnects 406.

Each of the external interconnects 406 includes a body 412 and a tip 414, wherein the tip 414 has a first connect side 416 and a second connect side 418 on an opposing side to the first connect side 416. The first integrated circuit device structure 404 is preferably mounted over the first connect side 416 with conductive balls 420, such as conductive balls or conductive bumps comprised of solder or gold, preferably electrically connecting a peripheral portion 422 of the first electrical contact side 410 of the first integrated circuit device structure 404 to the first connect side 416.

A second integrated circuit device structure 424, such as an integrated circuit package system having encapsulated integrated circuit devices, is preferably mounted under the first integrated circuit device structure 404 with an adhesive 426, such as an epoxy adhesive or a die-attach adhesive. The second integrated circuit device structure 424 is between the external interconnects 406.

The second integrated circuit device structure 424 preferably includes an encapsulation cover 428, such as an epoxy molding compound, and connection sites 430, such as terminal pads, exposed from the encapsulation cover 428. The encapsulation cover 428 preferably includes a second non-electrical contact side 440 and a second electrical contact side 442 that exposes the connection sites 430. The second non-electrical contact side 440 preferably faces an interior portion 432 of the first electrical contact side 410. The second integrated circuit device structure 424 may be electrically connected to the first integrated circuit device structure 404 by connecting with the same predetermined selection of the external interconnects 406 connected to the conductive balls 420. The connection sites 430 electrically connects to the second connect side 418 of the tip 414 with first wires 444, such as bond wires, ribbon bond wires, or reverse stand-off stitch bonds (RSSB).

A package encapsulation 402, such as an epoxy molding compound, covers the first integrated circuit device structure 404, the conductive balls 420, the second integrated circuit device structure 424, and the first wires 444. The package encapsulation 402 partially covers the external interconnects 406 exposing the body 412 of the external interconnects 406 and covering a portion of the tip 414 connected to the conductive balls 420 and the first wires 444.

For illustrative purposes, the first integrated circuit device structure 404 and the second integrated circuit device structure 424 are shown electrically connected by connecting the same predetermined selection of the external interconnects 406, although it is understood that the first integrated circuit device structure 404 and the second integrated circuit device structure 424 may be otherwise electrically connected. For example, the first wires 444 may connect the second integrated circuit device structure 424 to a predetermined selection of the external interconnects 406 not connected with the conductive balls 420.

Also for illustrative purposes, the integrated circuit package system 400 is shown with the second integrated circuit device structure 424 attached to the first integrated circuit device structure, however, it is understood that more than one additional integrated circuit device structures can be stacked and in a variety of possible configurations to create multiple and stacked integrated circuit device structures. For example, the first integrated circuit device structure 404 and the second integrated circuit device structure 424 can each also be of any type of integrated circuit device structures, such as an integrated circuit die, an integrated circuit package system having one or more integrated circuit dice, or a laminate having integrated circuit devices mounted thereon.

It has been discovered that the present invention provides an integrated circuit package system having stacked integrated circuits with reduced profile from mounting the first integrated circuit device structure, such as a flip chip, above the tip of the external interconnect and mounting a second integrated circuit device structure under the first integrated circuit device structure. The wires connecting the second integrated circuit device structure and the second connect side of the tip eliminates inadvertent connections between the first integrated circuit device structure and the second integrated circuit device structure.

It has also been discovered that the present invention increases integrated circuit device density in the integrated circuit package system by the elimination of a die-attach paddle (not shown) found in conventional packages that would have obstructed the routing of the additional wire bonds and additional integrated circuit device structures.

Referring now to FIG. 5, therein is shown a cross-sectional view of an integrated circuit package system 500 as exemplified by the bottom view of FIG. 1 along line 2--2 of FIG. 1 in a fourth embodiment of the present invention. The integrated circuit package system 500 is an example of an integrated circuit package-in-package system. The cross-sectional view depicts a first integrated circuit device structure 504 preferably mounted over external interconnects 506, such as leads. The first integrated circuit device structure 504, such as an integrated circuit package system having encapsulated integrated circuit devices, preferably includes an encapsulation cover 528, such as an epoxy molding compound, and connection sites 530, such as terminal pads, exposed from the encapsulation cover 528. The encapsulation cover 528 includes a first non-electrical contact side 508 and a first electrical contact side 510 that exposes the connection sites 530. The first electrical contact side 510 preferably faces the external interconnects 506 and the connection sites 530 faces away from the external interconnects 506. Conductive balls 520, such as conductive balls or conductive bumps comprised of solder or gold, preferably are attached to the connection sites 530 of the first integrated circuit device structure 504.

Each of the external interconnects 506 includes a body 512 and a tip 514, wherein the tip 514 has a first connect side 516 and a second connect side 518 on an opposing side to the first connect side 516. The first integrated circuit device structure 504 is preferably mounted over the first connect side 516 with the conductive balls 520 preferably electrically connecting a peripheral portion 522 of the first electrical contact side 510 of the first integrated circuit device structure 504 to the first connect side 516.

A second integrated circuit device structure 524, such as an integrated circuit die, is preferably mounted under the first integrated circuit device structure 504 with an adhesive 526, such as an epoxy adhesive or a die-attach adhesive. The second integrated circuit device structure 524 is between the external interconnects 506.

The second integrated circuit device structure 524 has a second non-electrical contact side 540, such as a non-active side, and a second electrical contact side 542, such as an active side, wherein the second electrical contact side 542 has active circuitry fabricated thereon. The second non-electrical contact side 540 preferably faces an interior portion 532 of the first electrical contact side 510. The second integrated circuit device structure 524 may be electrically connected to the first integrated circuit device structure 504 by connecting with the same predetermined selection of the external interconnects 506 connected to the conductive balls 520. The second electrical contact side 542 electrically connects to the second connect side 518 of the tip 514 with first wires 544, such as bond wires, ribbon bond wires, or reverse stand-off stitch bonds (RSSB).

A package encapsulation 502, such as an epoxy molding compound, covers the first integrated circuit device structure 504, the conductive balls 520, the second integrated circuit device structure 524, and the first wires 544. The package encapsulation 502 partially covers the external interconnects 506 exposing the body 512 of the external interconnects 506 and covering a portion of the tip 514 connected to the conductive balls 520 and the first wires 544.

For illustrative purposes, the first integrated circuit device structure 504 and the second integrated circuit device structure 524 are shown electrically connected by connecting the same predetermined selection of the external interconnects 506, although it is understood that the first integrated circuit device structure 504 and the second integrated circuit device structure 524 may be otherwise electrically connected. For example, the first wires 544 may connect the second integrated circuit device structure 524 to a predetermined selection of the external interconnects 506 not connected with the conductive balls 520.

Also for illustrative purposes, the integrated circuit package system 500 is shown with the second integrated circuit device structure 524 attached to the first integrated circuit device structure 504, however, it is understood that more than one additional integrated circuit device structures can be stacked and in a variety of possible configurations to create multiple and stacked integrated circuit device structures. For example, the first integrated circuit device structure 504 and the second integrated circuit device structure 524 can each also be of any type of integrated circuit device structures, such as an integrated circuit die, an integrated circuit package system having one or more integrated circuit dice, or a laminate having integrated circuit devices mounted thereon.

It has been discovered that the present invention provides an integrated circuit package system having stacked integrated circuits with reduced profile from mounting the first integrated circuit device structure, such as an integrated circuit package system having conductive balls, above the tip of the external interconnect and mounting a second integrated circuit device structure under the first integrated circuit device structure. The wires connecting the second integrated circuit device structure and the second connect side of the tip eliminates inadvertent connections between the first integrated circuit device structure and the second integrated circuit device structure.

It has also been discovered that the present invention increases integrated circuit device density in the integrated circuit package system by the elimination of a die-attach paddle (not shown) found in conventional packages that would have obstructed the routing of the additional wire bonds and the stacking of additional integrated circuit device structures.

Referring now to FIG. 6, therein is shown a cross-sectional view of an integrated circuit package system 600 as exemplified by the bottom view of FIG. 1 along line 2-2 of FIG. 1 in a fifth embodiment of the present invention. The cross-sectional view depicts a first integrated circuit device structure 604 preferably mounted over external interconnects 606, such as leads. The first integrated circuit device structure 604, such as a flip chip or an integrated circuit die, has a first non-electrical contact side 608, such as a non-active side, and a first electrical contact side 610, such as an active side, wherein the first electrical contact side 610 includes active circuitry fabricated thereon. The first electrical contact side 610 faces the external interconnects 606.

Each of the external interconnects 606 includes a body 612 and a tip 614, wherein the tip 614 has a first connect side 616 and a second connect side 618 on an opposing side to the first connect side 616. The first integrated circuit device structure 604 is preferably mounted over the first connect side 616 with conductive balls 620, such as conductive balls or conductive bumps comprised of solder or gold, preferably electrically connecting a peripheral portion 622 of the first electrical contact side 610 of the first integrated circuit device structure 604 to the first connect side 616.

A second integrated circuit device structure 624, such as a flip chip or an integrated circuit die, is preferably mounted under the first integrated circuit device structure 604 with an adhesive 626, such as an epoxy adhesive or a die-attach adhesive. The second integrated circuit device structure 624 has a second non-electrical contact side 640, such as a non-active side, and a second electrical contact side 642, such as an active side, wherein the second electrical contact side 642 has active circuitry fabricated thereon. The second non-electrical contact side 640 preferably faces an interior portion 632 of the first electrical contact side 610. The second integrated circuit device structure 624 may be electrically connected to the first integrated circuit device structure 604. The second electrical contact side 642 electrically connects to the second connect side 618 of the tip 614 with first wires 644, such as bond wires, ribbon bond wires, or reverse stand-off stitch bonds (RSSB).

A third integrated circuit device structure 634, such as an integrated circuit die, is preferably mounted over the first integrated circuit device structure 604 with the adhesive 626. The third integrated circuit device structure 634 has a third non-electrical contact side 636, such as a non-active side, and a third electrical contact side 638, such as an active side, wherein the third electrical contact side 638 has active circuitry fabricated thereon. The third non-electrical contact side 636 preferably faces the first non-electrical contact side 608. The third integrated circuit device structure 634 may be electrically connected to the first integrated circuit device structure 604 by connecting with the same predetermined selection of the external interconnects 606 connected to the conductive balls 620. The third electrical contact side 638 electrically connects to the first connect side 616 of the tip 614 with second wires 646, such as bond wires, ribbon bond wires, or reverse stand-off stitch bonds (RSSB).

A package encapsulation 602, such as an epoxy molding compound, covers the first integrated circuit device structure 604, the conductive balls 620, the second integrated circuit device structure 624, the first wires 644, the third integrated circuit device structure, and the second wires 646. The package encapsulation 602 partially covers the external interconnects 606 exposing the body 612 of the external interconnects 606 and covering a portion of the tip 614 connected to the conductive balls 620, the first wires 644, and the second wires 646.

For illustrative purposes, the first integrated circuit device structure 604, the second integrated circuit device structure 624, and the third integrated circuit device structure 634 are shown electrically connected by connecting the same predetermined selection of the external interconnects 606, although it is understood that the first integrated circuit device structure 604, the second integrated circuit device structure 624, and the third integrated circuit device structure 634 may be otherwise electrically connected. For example, the first wires 644 may connect the second integrated circuit device structure 624 to a predetermined selection of the external interconnects 606 not connected with the conductive balls 620. Likewise, the second wires 646 may connect the third integrated circuit device structure 634 to a predetermined selection of the external interconnects 606 not connected with the conductive balls 620.

Also for illustrative purposes, the integrated circuit package system 600 is shown with the second integrated circuit device structure 624 mounted under the first integrated circuit device structure 604 and the third integrated circuit device structure 634 over the first integrated circuit device structure 604, however, it is understood that more than one additional integrated circuit device structures can be stacked and in a variety of possible configurations to create multiple and stacked integrated circuit device structures. For example, the first integrated circuit device structure 604, the second integrated circuit device structure 624, and the third integrated circuit device structure 634 can each also be of any type of integrated circuit device structures, such as an integrated circuit die, an integrated circuit package system having one or more integrated circuit dice, or a laminate having integrated circuit devices mounted thereon.

It has been discovered that the present invention provides an integrated circuit package system having stacked integrated circuits with reduced profile from mounting the first integrated circuit device structure, such as a flip chip, above the tip of the external interconnect, mounting a second integrated circuit device structure under the first integrated circuit device structure, while mounting a third integrated circuit device structure over the first integrated circuit device structure. The wires connecting the second integrated circuit device and the second connect side of the tip eliminates inadvertent connections between the first integrated circuit device structure, the second integrated circuit device structure, and the third integrated circuit device structure.

It has also been discovered that the present invention increases integrated circuit device density in the integrated circuit package system by the elimination of a die-attach paddle (not shown) found in conventional packages that would have obstructed the routing of the additional wire bonds and the stacking of additional integrated circuit device structures.

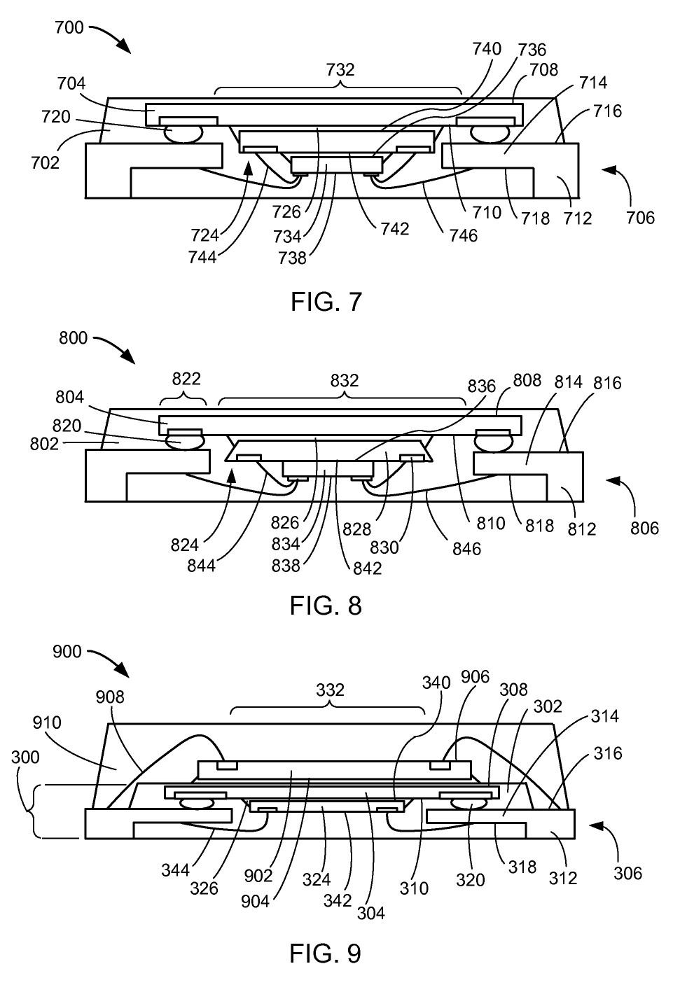

Referring now to FIG. 7, therein is shown a cross-sectional view of an integrated circuit package system 700 as exemplified by the bottom view of FIG. 1 along line 2-2 of FIG. 1 in a sixth embodiment of the present invention. The cross-sectional view depicts a first integrated circuit device structure 704 preferably mounted over external interconnects 706, such as leads. The first integrated circuit device structure 704, such as a flip chip or an integrated circuit die, has a first non-electrical contact side 708, such as a non-active side, and a first electrical contact side 710, such as an active side, wherein the first electrical contact side 710 includes active circuitry fabricated thereon. The first electrical contact side 710 faces the external interconnects 706.

Each of the external interconnects 706 includes a body 712 and a tip 714, wherein the tip 714 has a first connect side 716 and a second connect side 718 on an opposing side to the first connect side 716. The first integrated circuit device structure 704 is preferably mounted over the first connect side 716 with conductive balls 720, such as conductive balls or conductive bumps comprised of solder or gold, preferably electrically connecting a peripheral portion of the first electrical contact side 710 of the first integrated circuit device structure 704 to the first connect side 716.

A second integrated circuit device structure 724, such as an integrated circuit package system having a redistribution layer (RDL) or a laminate substrate for providing traces for integrated circuits, is preferably mounted under the first integrated circuit device structure 704 with an adhesive 726, such as an epoxy adhesive or a die-attach adhesive. The second integrated circuit device structure 724 has a second non-electrical contact side 740 and a second electrical contact side 742, wherein the second electrical contact side 742 has active circuitry fabricated thereon for the integrated circuit package system 700 having RDL or routing circuitry for the laminate substrate. The second non-electrical contact side 740 preferably faces an interior portion 732 of the first electrical contact side 710.

A third integrated circuit device structure 734, such as an integrated circuit die, is preferably mounted under the second integrated circuit device structure 724 with the adhesive 726. The third integrated circuit device structure 734 has a third non-electrical contact side 736, such as a non-active side, and a third electrical contact side 738, such as an active side, wherein the third electrical contact side 738 has active circuitry fabricated thereon. The third non-electrical contact side 736 preferably faces the second electrical contact side 742.

The third integrated circuit device structure 734 may be electrically connected to the first integrated circuit device structure 704 by connecting with the same predetermined selection of the external interconnects 706 connect to the conductive balls 720, by connecting to the second integrated circuit device structure 724, or a combination thereof. The third electrical contact side 738 electrically connects to the second connect side 718 of the tip 714 with second wires 746, such as bond wires, ribbon bond wires, or reverse stand-off stitch bonds (RSSB). The second integrated circuit device structure 724 may be electrically connected to the third integrated circuit device structure 734. The second electrical contact side 742 electrically connects to the third electrical contact side 738 with the second wires 746, such as bond wires, ribbon bond wires, or reverse stand-off stitch bonds (RSSB).

A package encapsulation 702, such as an epoxy molding compound, covers the first integrated circuit device structure 704, the conductive balls 720, the second integrated circuit device structure 724, first wires 744, the third integrated circuit device structure 734, and the second wires 746. The package encapsulation 702 partially covers the external interconnects 706 exposing the body 712 of the external interconnects 706 and covering a portion of the tip 714 connected to the conductive balls 720 and the first wires 744.

For illustrative purposes, the first integrated circuit device structure 704, the second integrated circuit device structure 724, and the third integrated circuit device structure 734 are electrically connected as illustrated. However, it is understood that the first integrated circuit device structure 704, the second integrated circuit device structure 724, and the third integrated circuit device structure 734 may be otherwise electrically connected. For example, the first wires 744 may connect the second integrated circuit device structure 724 to a predetermined selection of the external interconnects 706 not connected with the conductive balls 720. Likewise, the second wires 746 may connect the third integrated circuit device structure 734 to a predetermined selection of the external interconnects 706 not connected with the conductive balls 720.

Also for illustrative purposes, the integrated circuit package system 700 is shown with the second integrated circuit device structure 724 and the third integrated circuit device structure 734 under the first integrated circuit device structure 704. However, it is understood that a different number of integrated circuit device structures can be stacked and in a variety of possible configurations to create multiple and stacked integrated circuit device structures. The first integrated circuit device structure 704, the second integrated circuit device structure 724, and the third integrated circuit device structure 734 can each also be of any type of integrated circuit device structures, such as an integrated circuit die, an integrated circuit package system having one or more integrated circuit dice, or a laminate having integrated circuit devices mounted thereon.

It has been discovered that the present invention provides an integrated circuit package system having stacked integrated circuits with reduced profile from mounting the first integrated circuit device structure above the tip of the external interconnect and mounting one or more additional integrated circuit device structures under the first integrated circuit device structure. The wires connecting the one or more integrated circuit device structures and the second connect side of the tip reduces inadvertent connections between the one or more additional integrated circuit device structures.

It has also been discovered that the present invention increases integrated circuit device density in the integrated circuit package system by the elimination of a die-attach paddle (not shown) found in conventional packages that would have obstructed the routing of the additional wire bonds and the stacking of additional integrated circuit device structures.

Referring now to FIG. 8, therein is shown a cross-sectional view of an integrated circuit package system 800 as exemplified by the bottom view of FIG. 1 along line 2-2 of FIG. 1 in a seventh embodiment of the present invention. The integrated circuit package system 800 is an example of an integrated circuit package-in-package system. The cross-sectional view depicts a first integrated circuit device structure 804 preferably mounted over external interconnects 806, such as leads. The first integrated circuit device structure 804, such as an integrated circuit package system having a redistribution layer (RDL) or a laminate substrate providing traces for integrated circuits, has a first non-electrical contact side 808 and a first electrical contact side 810, wherein the first electrical contact side 810 includes active circuitry fabricated thereon for the integrated circuit package system 800 with the RDL or routing circuitry for the laminate substrate. The first electrical contact side 810 faces the external interconnects 806.

Each of the external interconnects 806 includes a body 812 and a tip 814, wherein the tip 814 has a first connect side 816 and a second connect side 818 on an opposing side to the first connect side 816. The first integrated circuit device structure 804 is preferably mounted over the first connect side 816 with conductive balls 820, such as conductive balls or conductive bumps comprised of solder or gold, preferably electrically connecting a peripheral portion 822 of the first electrical contact side 810 of the first integrated circuit device structure 804 to the first connect side 816.

A second integrated circuit device structure 824, such as an integrated circuit package system having encapsulated integrated circuit devices, is preferably mounted under the first integrated circuit device structure 804 with an adhesive 826, such as an epoxy adhesive or a die-attach adhesive. The second integrated circuit device structure 824 is between the external interconnects 806.

The second integrated circuit device structure 824 preferably includes an encapsulation cover 828, such as an epoxy molding compound, and connection sites 830, such as terminal pads, exposed from the encapsulation cover 828. The encapsulation cover 828 preferably faces an interior portion 832 of the first electrical contact side 810 and the connection sites 830 faces away from the first integrated circuit device structure 804. The second integrated circuit device structure 824 may be electrically connected to the first integrated circuit device structure 804 by connecting with the same predetermined selection of the external interconnects 806 connected to the conductive balls 820.

A third integrated circuit device structure 834, such as an integrated circuit die, is preferably mounted under the second integrated circuit device structure 824 with the adhesive 826. The third integrated circuit device structure 834 has a third non-electrical contact side 836, such as a non-active side, and a third electrical contact side 838, such as an active side, wherein the third electrical contact side 838 has active circuitry fabricated thereon. The third non-electrical contact side 836 preferably faces a second electrical contact side 842.

The third integrated circuit device structure 834 may be electrically connected to the first integrated circuit device structure 804 by connecting with the same predetermined selection of the external interconnects 806 connected to the conductive balls 820. The connection sites 830 of the second integrated circuit device structure 824 preferably electrically connect to the third electrical contact side 838 with first wires 844, such as bond wires, ribbon bond wires, or reverse stand-off stitch bonds (RSSB). The third electrical contact side 838 preferably electrically connects to the second connect side 818 of the tip 814 with second wires 846, such as bond wires, ribbon bond wires, or reverse stand-off stitch bonds (RSSB).

A package encapsulation 802, such as an epoxy molding compound, covers the first integrated circuit device structure 804, the conductive balls 820, the second integrated circuit device structure 824, the first wires 844, the third integrated circuit device structure 834, and the second wires 846. The package encapsulation 802 partially covers the external interconnects 806 exposing the body 812 of the external interconnects 806 and covering a portion of the tip 814 connected to the conductive balls 820 and the first wires 844.

For illustrative purposes, the first integrated circuit device structure 804, the second integrated circuit device structure 824, and the third integrated circuit device structure 834 are electrically connected as illustrated. However, it is understood that the first integrated circuit device structure 804, the second integrated circuit device structure 824, and the third integrated circuit device structure 834 may be otherwise electrically connected. For example, the first wires 844 may connect the second integrated circuit device structure 824 to a predetermined selection of the external interconnects 806 not connected with the conductive balls 820. Likewise, the second wires 846 may connect the third integrated circuit device structure 834 to a predetermined selection of the external interconnects 806 not connected with the conductive balls 820.

Also for illustrative purposes, the integrated circuit package system 800 is shown with the second integrated circuit device structure 824 and the third integrated circuit device structure 834 under the first integrated circuit device structure 804. However, it is understood that more than one additional integrated circuit device structures can be stacked and in a variety of possible configurations to create multiple and stacked integrated circuit device structures. The first integrated circuit device structure 804, the second integrated circuit device structure 824, and the third integrated circuit device structure 834 can each also be of any type of integrated circuit device structures, such as an integrated circuit die, an integrated circuit package system having one or more integrated circuit dice, or a laminate having integrated circuit devices mounted thereon.

It has been discovered that the present invention provides an integrated circuit package system having stacked integrated circuits with reduced profile from mounting the first integrated circuit device structure above the tip of the external interconnect and mounting one or more additional integrated circuit device structures under the first integrated circuit device structure. The wires connecting one or more additional integrated circuit device structures and the second connect side of the tip reduces inadvertent connections between the first and the one or more additional integrated circuit device structures.

It has also been discovered that the present invention increases integrated circuit device density in the integrated circuit package system by the elimination of a die-attach paddle (not shown) found in conventional packages that would have obstructed the routing of the additional wire bonds and additional integrated circuit device structures.

Referring now to FIG. 9, therein is shown a cross-sectional view of an integrated circuit package system 900 as exemplified by the bottom view of FIG. 1 along line 2-2 of FIG. 1 in a eighth embodiment of the present invention. The cross-sectional view depicts the first integrated circuit device structure 304 preferably mounted over the external interconnects 306, such as leads. The first integrated circuit device structure 304, such as a flip chip or an integrated circuit die, has the first non-electrical contact side 308, such as a non-active side, and the first electrical contact side 310, such as an active side, wherein the first electrical contact side 310 includes active circuitry fabricated thereon. The first electrical contact side 310 faces the external interconnects 306.

Each of the external interconnects 306 includes the body 312 and the tip 314, wherein the tip 314 has the first connect side 316 and the second connect side 318 on an opposing side to the first connect side 316. The first integrated circuit device structure 304 is preferably mounted over the first connect side 316 with the conductive balls 320, such as conductive balls or conductive bumps comprised of solder or gold, preferably electrically connecting a peripheral portion of the first electrical contact side 310 of the first integrated circuit device structure 304 to the first connect side 316.

The second integrated circuit device structure 324, such as a flip chip or an integrated circuit die, is preferably mounted under the first integrated circuit device structure 304 with the adhesive 326, such as an epoxy adhesive or a die-attach adhesive. The second integrated circuit device structure 324 is between the external interconnects 306.

The second integrated circuit device structure 324 has the second non-electrical contact side 340, such as a non-active side, and the second electrical contact side 342, such as an active side, wherein the second electrical contact side 342 has active circuitry fabricated thereon. The second non-electrical contact side 340 preferably faces the interior portion 332 of the first electrical contact side 310. The second integrated circuit device structure 324 electrically connects to the second connect side 318 with first wires, such as bond wires, ribbon bond wires, or reverse stand-off stitch bonds (RSSB).

The package encapsulation 302, such as an epoxy molding compound, covers the first integrated circuit device structure 304, the conductive balls 320, the second integrated circuit device structure 324, and the first wires 344. The package encapsulation 302 also partially covers the external interconnects 306 exposing the body 312 of the external interconnects 306 and covering a portion of the tip 314 connected to the conductive balls 320 and the first wires 344 forming the integrated circuit package system 300.

A third integrated circuit device structure 902, such as an integrated circuit die, is preferably mounted over the package encapsulation 302 with the adhesive 326. The third integrated circuit device structure 902 has a third non-electrical contact side 904, such as a non-active side, and a third electrical contact side 906, such as an active side, wherein the third electrical contact side 906 has active circuitry fabricated thereon. The third non-electrical contact side 904 preferably faces the package encapsulation 302.

The third integrated circuit device structure 902 may be electrically connected to the first integrated circuit device structure 304, the second integrated circuit device structure 324, or combination thereof. The third electrical contact side 906 electrically connects to the second connect side 318 of the tip 314 exposed by the package encapsulation 302 with second wires 908, such as bond wires, ribbon bond wires, or reverse stand-off stitch bonds (RSSB).

An encapsulation cover 910, such as an epoxy molding compound, covers the third integrated circuit device structure 902 and the second wires 908. The encapsulation cover 910 partially covers the package encapsulation 302 and the external interconnects 306.

For illustrative purposes, the first integrated circuit device structure 304, the second integrated circuit device structure 324, and the third integrated circuit device structure 902 are electrically connected as illustrated. However, it is understood that the first integrated circuit device structure 304, the second integrated circuit device structure 324, and the third integrated circuit device structure 902 may be otherwise electrically connected. For example, the first wires 344 may connect the second integrated circuit device structure 324 to a predetermined selection of the external interconnects 306 not connected with the conductive balls 320. Likewise, the second wires 908 may connect the third integrated circuit device structure 902 to a predetermined selection of other external interconnects.

It has been discovered that the present invention provides an integrated circuit package system having stacked integrated circuits with reduced profile from mounting the first integrated circuit device structure above the tip of the external interconnect and mounting a second integrated circuit device structure under the first integrated circuit device structure. The wires connecting the second and third integrated circuit device structures and the second connect side of the tip reduces inadvertent connections between the first, second and third integrated circuit device structures.

It has also been discovered that the present invention increases integrated circuit device density in the integrated circuit package system by the elimination of a die-attach paddle (not shown) found in conventional packages that would have obstructed the routing of the additional wire bonds and additional integrated circuit device structures.

It has been further discovered that the present invention provides additional stacking of integrated circuit device structures for forming a low profile package-in-package configuration. Another integrated circuit die may be stacked on encapsulation of the integrated circuit package system and connecting to the internal integrated circuits by connecting to the exposed portion of the tip of the external interconnects.

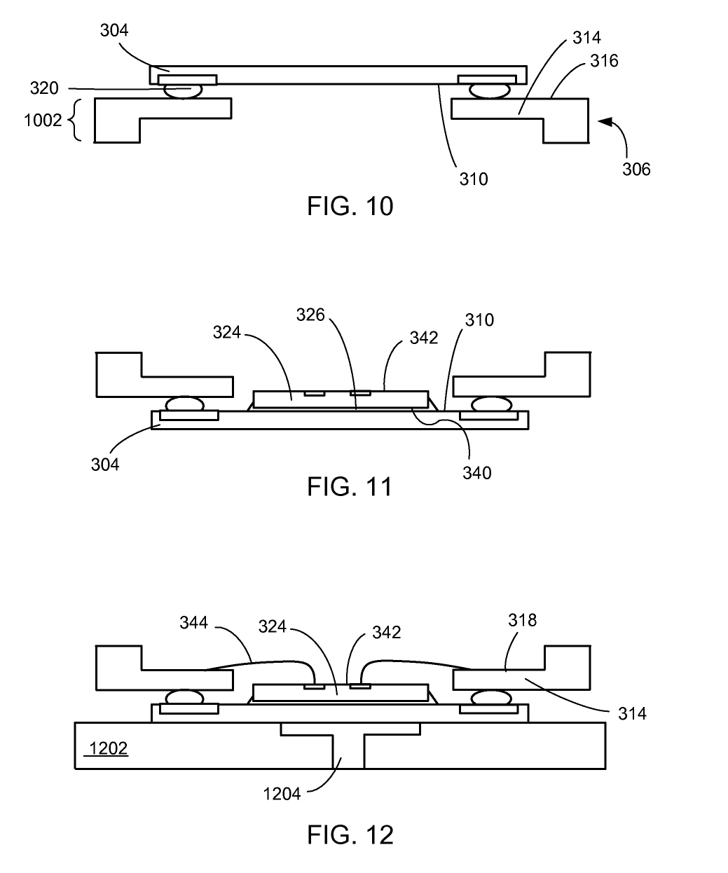

Referring now to FIG. 10, therein is shown a cross-sectional view of a lead frame 1002 in a mounting phase of the first integrated circuit device structure 304. The first integrated circuit device structure 304 having the conductive balls 320 connect to the tip 314 of the external interconnects 306 with the first electrical contact side 310 of the first integrated circuit device structure 304 facing the first connect side 316 of the tip 314.

Referring now to FIG. 11, therein is shown the structure of FIG. 10 in a vertically flipped orientation in a mounting phase of the second integrated circuit device structure 324. The second integrated circuit device structure 324 has the second electrical contact side 342 and the second non-electrical contact side 340 with the second non-electrical contact side 340 mounted over the first electrical contact side 310 of the first integrated circuit device structure 304 with the adhesive 326.

Referring now to FIG. 12 therein is shown the structure of FIG. 11 in a connecting phase of the first wires 344. The structure of FIG. 11 is shown mounted on a holding structure 1202 with an opening 1204. A vacuum force through the opening 1204 preferably secures the structure of FIG. 11 for attaching the first wires 344. The first wires 344 electrically connects the second electrical contact side 342 of the second integrated circuit device structure 324 to the second connect side 318 on the tip 314.

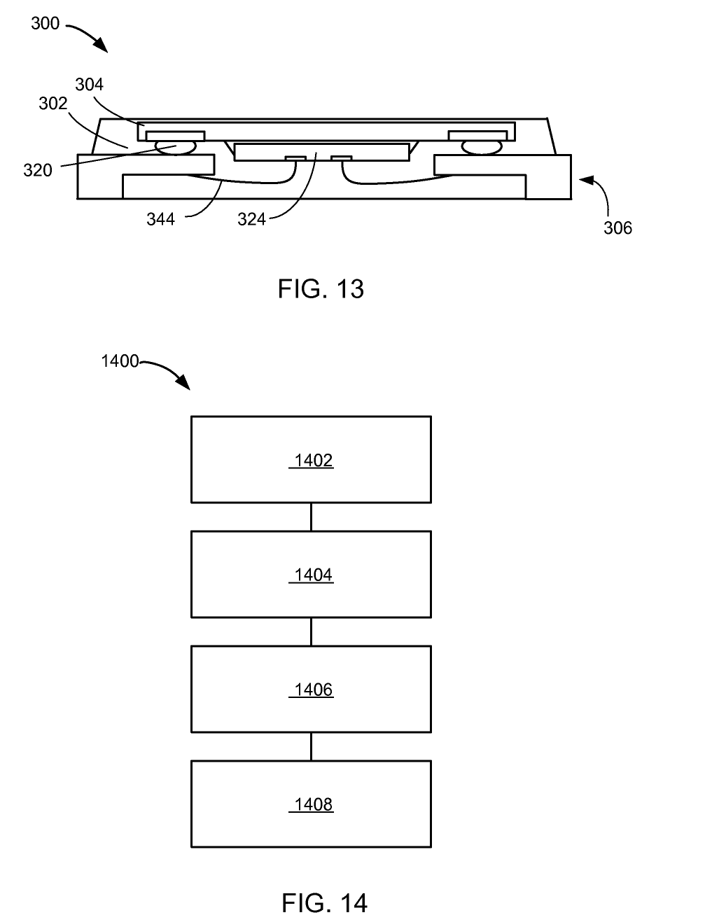

Referring now to FIG. 13, therein is shown the structure of FIG. 12 in a non-vertically flipped orientation in a forming phase of the package encapsulation 302. The structure of FIG. 12 undergoes a molding process forming the package encapsulation 302. The package encapsulation 302 encapsulates the first integrated circuit device structure 304, the second integrated circuit device structure 324, the conductive balls 320, and the first wires 344. The structure having the package encapsulation 302 may undergo a singulation process separating the integrated circuit package system 300 from the lead frame 1002 of FIG. 10 and forming the external interconnects 306.

Referring now to FIG. 14, therein is shown a flow chart of an integrated circuit package system 1400 for manufacturing the integrated circuit package system 100 in an embodiment of the present invention. The system 1400 includes forming an external interconnect having a tip without a die-attach paddle in a block 1402; mounting a first integrated circuit device structure having a conductive ball over the tip in a block 1404; connecting a first wire between the first integrated circuit device structure and under the tip in a block 1406; and encapsulating the first integrated circuit device structure, the first wire, and the external interconnect with the external interconnect partially exposed in a block 1408.

It has been discovered that the present invention increases integrated circuit device density in the integrated circuit package system. Moreover, having a first and a second connect side on the tip of the external interconnect not only increases wire connections to the integrated circuit device structures, but also reduces inadvertent connections to the integrated circuit device structures.

It has also been discovered that the present invention increases integrated circuit device density in the integrated circuit package system by the elimination of a die-attach paddle (not shown) found in conventional packages that would have obstructed the routing of the additional wire bonds and additional integrated circuit device structures.

Yet another important aspect of the present invention is that it valuably supports and services the historical trend of reducing costs, simplifying systems, and increasing performance.

These and other valuable aspects of the present invention consequently further the state of the technology to at least the next level.

Thus, it has been discovered that the integrated circuit package system of the present invention furnishes important and heretofore unknown and unavailable solutions, capabilities, and functional aspects for improving yield, increasing reliability, and reducing cost of integrated circuit package system. The resulting processes and configurations are straightforward, cost-effective, uncomplicated, highly versatile, accurate, sensitive, and effective, and can be implemented by adapting known components for ready, efficient, and economical manufacturing, application, and utilization.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. An integrated circuit package system comprising:
forming an external interconnect having a tip without a die-attach paddle;
mounting a first integrated circuit device structure having a conductive ball over the tip;
connecting a first wire between the first integrated circuit device structure and under the tip; and
encapsulating the first integrated circuit device structure, the first wire, and the external interconnect with the external interconnect partially exposed.

2. The system as claimed in claim 1 wherein mounting the first integrated circuit device structure includes mounting a flip chip.

3. The system as claimed in claim 1 wherein mounting the first integrated circuit device structure includes mounting an integrated circuit package.

4. The system as claimed in claim 1 wherein mounting the first integrated circuit device structure includes mounting a laminate substrate.

5. The system as claimed in claim 1 wherein mounting the first integrated circuit device structure includes mounting an integrated circuit die.

6. An integrated circuit package system comprising:
forming an external interconnect having a body and a tip without a die-attach paddle, the tip having a first connect side and a second connect side;
mounting a first integrated circuit device structure having a conductive ball over the first connect side;
connecting a first wire between the first integrated circuit device structure and the second connect side; and
encapsulating the first integrated circuit device structure, the first wire, and the external interconnect with the external interconnect partially exposed.

7. The system as claimed in claim 6 wherein mounting the first integrated circuit device structure includes mounting an integrated circuit die.

8. The system as claimed in claim 6 wherein:
mounting the first integrated circuit device structure having the conductive ball over the first connect side includes:
connecting the conductive ball with the first connect side;
mounting a second integrated circuit device structure under the first integrated circuit device structure; and
connecting the first wire includes:
connecting the first wire between the second integrated circuit device structure and the second connect side.

9. The system as claimed in claim 6 further comprising:
mounting a second integrated circuit device structure over the first integrated circuit device structure; and
connecting a second wire between the second integrated circuit device structure and the first connect side.

10. The system as claimed in claim 6 wherein:
encapsulating the first integrated circuit device structure includes:
forming a package encapsulation;
further comprising:
mounting a second integrated circuit device structure over the package encapsulation;
connecting a second wire between the second integrated circuit device structure and the first connect side; and
forming an encapsulation cover over the second integrated circuit device structure and the second wire.

11. An integrated circuit package system comprising:
an external interconnect having a tip without a die-attach paddle;
a first integrated circuit device structure having a conductive ball over the tip;
a first wire between the first integrated circuit device structure and connected to the tip under the tip; and
a package encapsulation over the first integrated circuit device structure, the first wire, and the external interconnect with the external interconnect partially exposed.

12. The system as claimed in claim 11 wherein the first integrated circuit device structure includes a flip chip.

13. The system as claimed in claim 11 wherein the first integrated circuit device structure includes an integrated circuit package.

14. The system as claimed in claim 11 wherein the first integrated circuit device structure includes a laminate substrate.

15. The system as claimed in claim 11 wherein the first integrated circuit device structure includes an integrated circuit die.

16. The system as claimed in claim 11 wherein:
the external interconnect has a body and the tip having both a first connect side and a second connect side;
the first integrated circuit device structure has the conductive ball over the first connect side;
the first wire is between first integrated circuit device structure and the second connect side; and
the package encapsulation partially exposes the body.

17. The system as claimed in claim 16 wherein the first integrated circuit device structure includes an integrated circuit die.

18. The system as claimed in claim 16 wherein:
the first integrated circuit device structure having the conductive ball over the first connect side includes:
the conductive ball connected to the first connect side;
a second integrated circuit device structure under the first integrated circuit device structure; and
the first wire includes:
the first wire between the second integrated circuit device structure and the second connect side.

19. The system as claimed in claim 16 further comprising:
a second integrated circuit device structure over the first integrated circuit device structure; and
a second wire between the second integrated circuit device structure and the first connect side.

20. The system as claimed in claim 16 further comprising:
a second integrated circuit device structure over the package encapsulation;
a second wire between the second integrated circuit device structure and the first connect side; and
an encapsulation cover over the second integrated circuit device structure and the second wire.
